(19) United States
(12) Patent Application Publication
(10) Pub. No.: US 2026/0316550 A1
(43) Pub. Date: Oct. 15, 2026

(54) BATTERY ELECTRIC VEHICLE

(71) Applicant: TOYOTA JIDOSHA KABUSHIKI KAISHA, Toyota-shi (JP)

(72) Inventors: Hirofumi KAMISHIMA, Toyota-shi (JP); Akitaka Ichikawa, Nisshin-shi (JP); Tatsuhiro Hashida, Nagoya-shi (JP); Eiji Murase, Nagoya-shi (JP); Yuta Kugimachi, Nagoya-shi (JP)

(73) Assignee: TOYOTA JIDOSHA KABUSHIKI KAISHA, Toyota-shi (JP)

(21) Appl. No.: 19/549,624

(22) Filed: Feb. 25, 2026

(30) Foreign Application Priority Data
Apr. 11, 2025 (JP) 2025-065572

(51) Int. Cl. B60K 7/00; B60K 1/04; B60L 50/51; B60L 53/22; H05K 7/20; B60K 1/00

(52) U.S. Cl. CPC B60K 7/0007; B60K 1/04; B60L 50/51; B60L 53/22; H05K 7/20872; B60K 2001/003; B60K 2001/0438; B60L 2210/14; B60L 2210/30; B60L 2210/40

(57) ABSTRACT

A battery electric vehicle includes a drive device, electric equipment (power conversion device), a condenser, and a front grille. The drive device includes a motor and reducer transmitting rotations by the motor to a drive shaft. The drive device has a uniaxial structure where the reducer and the drive shaft are disposed on an extension of a rotation axis of the motor, and is disposed between front wheels on right and left sides. The electrical equipment is disposed above the drive device. The condenser is disposed forward the drive device. The front grille is disposed forward the condenser. The condenser is inclined such that an upper end of a front face portion receiving outside air from the front grille is forward a lower end of the front face portion. The upper end of the front face portion is at a position lower than an upper end of the electric equipment.

### CROSS-REFERENCE TO RELATED APPLICATION

This application claims priority to Japanese Patent Application No. 2025-065572 filed on April 11, 2025. The disclosure of the above-identified application, including the specification, drawings, and claims, is incorporated by reference herein in its entirety.

### BACKGROUND

### 1. Technical Field

The present disclosure provides relates to a battery electric vehicle.

### 2. Description of Related Art

Japanese Unexamined Patent Application Publication No. 2021-079765 (JP 2021-079765 A) describes layout of equipment in a compartment forward in a vehicle.

### SUMMARY

There is demand for a battery electric vehicle that is a sportscar-type battery electric vehicle. In order to realize sportscar-like proportions in a battery electric vehicle, lowering vehicle height at a vehicle forward portion is desirable. There is room for improvement in layout of equipment in a compartment situated in a forward portion in the vehicle, in order to realize such sportscar-like proportions.

A battery electric vehicle that solves the above problem is a battery electric vehicle in which front wheels are driven by electricity supplied from a battery. This battery electric vehicle includes a drive device having a motor and a reducer that transmits rotation by the motor to a drive shaft, electrical equipment, a condenser that cools refrigerant gas by outside air, and a front grille for supplying outside air to the condenser. The drive device is of a uniaxial structure in which the reducer and the drive shaft are disposed on an extension of a rotation axis of the motor, and is disposed between the front wheels on right and left sides. The electric equipment is disposed above the drive device. The condenser is disposed forward of the drive device. The front grille is disposed forward of the condenser. The condenser is inclined such that an upper end of a front face portion that receives outside air from the front grille is situated forward of a lower end of the front face portion, and the upper end of the front face portion is situated at a position lower than an upper end of the electric equipment.

The battery electric vehicle described above can realize sportscar-like proportions.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic diagram illustrating a layout of equipment in a compartment of a battery electric vehicle according to one embodiment, as viewed from a side;

FIG. 2 is a schematic diagram illustrating the layout of the equipment in the compartment of the battery electric vehicle illustrated in FIG. 1, as viewed from upward;

FIG. 3 is a schematic diagram illustrating a configuration of a drive device that the battery electric vehicle of FIG. 1 is equipped with;

FIG. 4 is a schematic diagram illustrating a layout of equipment in the compartment of the battery electric vehicle according to a first modification, as viewed from the side;

FIG. 5 is a schematic diagram illustrating a layout of equipment in the compartment of the battery electric vehicle according to a second modification, as viewed from the side; and

FIG. 6 is a schematic diagram illustrating a layout of equipment in the compartment of the battery electric vehicle according to a third modification, as viewed from the side.

### DETAILED DESCRIPTION OF EMBODIMENTS

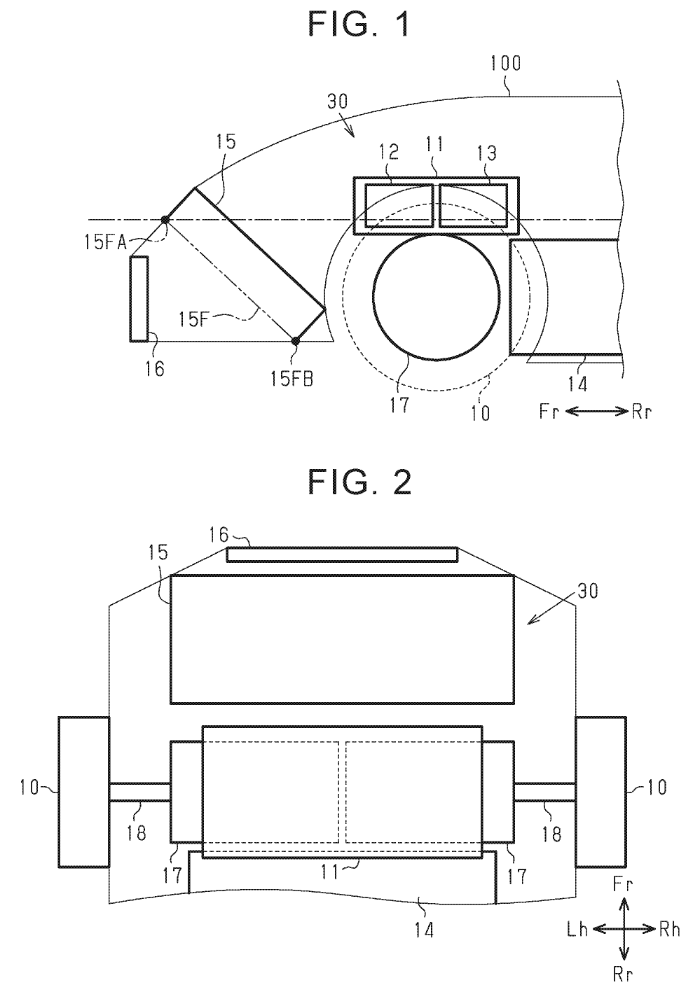

In FIGS. 1, 2, and 4 to 6, directions are indicated by arrows. In FIGS. 1, 2, and 4 to 6, Fr indicates a forward direction of the battery electric vehicle 100. In FIGS. 1, 2, and 4 to 6, Rr indicates a rearward direction of the battery electric vehicle 100. In FIG. 2, Rh indicates a right side of an occupant facing forward in the battery electric vehicle 100. In FIG. 2, Lh indicates a left side of an occupant facing forward in the battery electric vehicle 100.

Hereinafter, an embodiment of a battery electric vehicle will be described with reference to FIGS. 1 to 3.

### Layout and Configuration of Drive Device 17

The battery electric vehicle 100 has a compartment 30 forward in the vehicle, in which equipment is laid out. FIG. 1 illustrates layout of equipment in the compartment 30 when the battery electric vehicle 100 is viewed from the left side of an occupant facing forward in the battery electric vehicle 100. FIG. 2 illustrates the layout of the equipment in the compartment 30 of the battery electric vehicle 100 as viewed from upward.

As illustrated in FIGS. 1 and 2, the battery electric vehicle 100 includes drive devices 17. As illustrated in FIG. 2, the drive devices 17 are disposed between right and left front wheels 10.

As illustrated in FIG. 2, in the battery electric vehicle 100, two drive devices 17 are laid out in the compartment 30. In FIG. 2, the drive device 17 disposed on the right side is connected to the right front wheel of the front wheels 10 via a drive shaft 18. In FIG. 2, the drive device 17 disposed on the left side is connected to the left front wheel of the front wheels 10 via a drive shaft 18.

As illustrated in FIGS. 1 and 2, the battery electric vehicle 100 includes a battery 14. As illustrated in FIGS. 1 and 2, the battery 14 is disposed rearward of the drive device 17. The drive device 17 drives the front wheels 10 by electricity supplied from the battery 14.

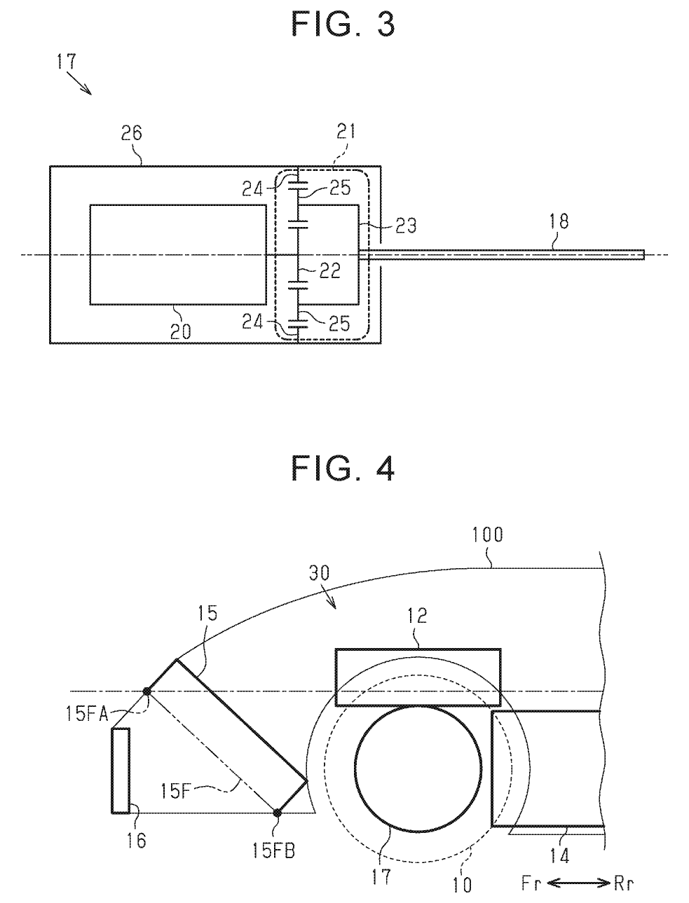

FIG. 3 illustrates a configuration of the drive device 17 provided in the battery electric vehicle 100.

As illustrated in FIG. 3, the drive device 17 includes a motor 20 and a reducer 21. In the drive device 17, the motor 20 and the reducer 21 are enclosed in a housing 26.

As illustrated in FIG. 3, the reducer 21 includes a sun gear 22, a planetary carrier 23 that rotatably supports a plurality of pinion gears 25, and a ring gear 24. That is to say, the reducer 21 includes a planetary gear mechanism.

As illustrated in FIG. 3, in the drive device 17, the motor 20 is connected to the sun gear 22 in the reducer 21. In the reducer 21, the pinion gears 25 supported by the planetary carrier 23 are disposed between the sun gear 22 and the ring gear 24. The pinion gears 25 mesh with both the sun gear 22 and the ring gear 24. In the reducer 21, the ring gear 24 is fixed to the housing 26.

As illustrated in FIG. 3, the planetary carrier 23 is connected to the drive shaft 18. The motor 20 is driven by electricity stored in the battery 14. In the drive device 17, rotations generated by the motor 20 are transmitted to the sun gear 22, the planetary carrier 23, and the drive shaft 18, in this order. At this time, due to the difference in the number of teeth provided to the sun gear 22, the pinion gears 25, and the ring gear 24, the rotations generated by the motor 20 are reduced before being transmitted to the drive shaft 18. Thus, the reducer 21 reduces the speed of rotations of the motor 20 and then performs transmission thereof to the drive shaft 18.

The long dashed short dashed line in FIG. 3 indicates a rotation axis of rotations generated by the motor 20. As illustrated in FIG. 3, in the drive device 17, the reducer 21 and the drive shaft 18 are disposed on an extension of the rotation axis of the motor 20. That is to say, the drive device 17 has a uniaxial structure.

In FIG. 2, the drive device 17 disposed on the right side rotates the right front wheel through the drive shaft 18. In FIG. 2, the drive device 17 disposed on the left side rotates the left front wheel through the drive shaft 18.

### Layout of Equipment in Compartment 30

Electrical equipment that runs on electricity is disposed above the drive device 17. As illustrated in FIGS. 1 and 2, the battery electric vehicle 100 includes a power conversion device 11 serving as electric equipment installed above the drive device 17.

As illustrated in FIG. 1, in the power conversion device 11, a direct current (DC)-to-DC converter 12 and an on-board charger 13 are integrated together.

The DC-to-DC converter 12 boosts the voltage of external electricity and supplies the electricity that is boosted to the battery 14. For example, the DC-to-DC converter 12 boosts the voltage of electricity from a charging station for rapid charging, and also supplies the electricity that is boosted to the battery 14.

The on-board charger 13 converts external alternating current electricity into direct current electricity and also supplies the direct current to the battery 14. For example, the on-board charger 13 converts alternating current electricity from a normal charging outlet into direct current electricity, and also supplies the direct current electricity to the battery 14.

As illustrated in FIGS. 1 and 2, the battery electric vehicle 100 includes a condenser 15. As illustrated in FIGS. 1 and 2, the condenser 15 is disposed forward of the drive device 17. The condenser 15 has a pipe through which refrigerant gas of a car air conditioner flows. The condenser 15 cools the refrigerant gas by heat exchange between the refrigerant gas and outside air.

As illustrated in FIGS. 1 and 2, the battery electric vehicle 100 includes a front grille 16. As illustrated in FIGS. 1 and 2, the front grille 16 is disposed forward of the condenser 15. The front grille 16 is situated at a front end portion of the vehicle. The front grille 16 takes in outside air from outside of the vehicle, and also supplies the outside air that is taken into the condenser 15.

In FIG. 1, a front face portion 15F of the condenser 15 is indicated by a long dashed double-short dashed line. The front face portion 15F of the condenser 15 is a face that faces the front grille 16 and also receives outside air from the front grille 16.

In FIG. 1, an upper end 15FA of the front face portion 15F and a lower end 15FB of the front face portion 15F are illustrated. As illustrated in FIG. 1, the condenser 15 is inclined such that the upper end 15FA is situated forward of the lower end 15FB.

The long dashed short dashed line in FIG. 1 indicates height of the upper end 15FA of the front face portion 15F. As illustrated in FIG. 1, the upper end 15FA is situated at a position lower than an upper end of the power conversion device 11.

### Effects of Present Embodiment

The drive device 17 in the battery electric vehicle 100 has a uniaxial structure, not a multiaxial structure. The drive device 17 with the uniaxial structure has the motor 20 and the reducer 21 arrayed in a direction in which the rotation axis extends. Accordingly, although the drive device 17 with the uniaxial structure has a larger dimension in a vehicle width direction than a drive device 17 with a multiaxial structure, the dimensions in a vehicle front-rear direction and vehicle up-down direction are compact. Thus, the portion of the compartment 30 where the drive device 17 is disposed in the battery electric vehicle 100 described above is lower than the portion in a battery electric vehicle 100 equipped with the drive device 17 with a multiaxial structure.

Also, in the battery electric vehicle 100 described above, the condenser 15 is disposed obliquely in space forward of the drive device 17, which is secured by making the drive device 17 compact. Accordingly, the height at which the upper end of the condenser 15 is situated is lower as compared to when the front face portion 15F is disposed perpendicular to the ground, while maintaining the state of the front face portion 15F that receives wind from the front grille 16 facing the front grille 16. Accordingly, in the battery electric vehicle 100 described above, the portion of the compartment 30 where the condenser 15 is disposed is lower than when the front face portion 15F is disposed perpendicular to the ground.

In this way, in the battery electric vehicle 100 described above, the portion of the compartment 30 where the drive device 17 and the condenser 15 are disposed is lowered, thereby lowering the vehicle height at the vehicle forward portion.

### Advantages of Present Embodiment

(1) The battery electric vehicle 100 described above can realize sportscar-like proportions.

(2) The electrical equipment is the power conversion device 11, in which are integrated the DC-to-DC converter 12 that boosts voltage of external electricity and performs supply thereof to the battery 14, and the on-board charger 13 that converts external alternating current electricity into direct current electricity and performs supply thereof to the battery 14.

### Modifications

The present embodiment can be carried out modified as follows. The above embodiment and the following modifications can be implemented in combination with each other insofar as no technical contradiction arises.

As illustrated in FIGS. 1 and 2, in the battery electric vehicle 100 described above, the battery 14 is disposed directly behind the drive device 17. In the battery electric vehicle 100, the location where the battery 14 is disposed is not limited to that in the above embodiment. For example, the battery 14 may be disposed under a floor of a cabin of the battery electric vehicle 100.

The electrical equipment disposed above the drive device 17 is not limited to the power conversion device 11.

FIG. 4 illustrates layout of equipment in the compartment 30 when the battery electric vehicle 100 according to a first modification is viewed from the left side of an occupant facing forward in the battery electric vehicle 100.

As illustrated in FIG. 4, the battery electric vehicle 100 according to the first modification includes the DC-to-DC converter 12 as electric equipment installed above the drive device 17.

The long dashed short dashed line in FIG. 4 indicates the height of the upper end 15FA of the front face portion 15F. As illustrated in FIG. 4, the upper end 15FA is situated at a position lower than the upper end of the DC-to-DC converter 12.

In this case, the electric equipment is the DC-to-DC converter 12 that boosts the voltage of external electricity and performs supply thereof to the battery 14.

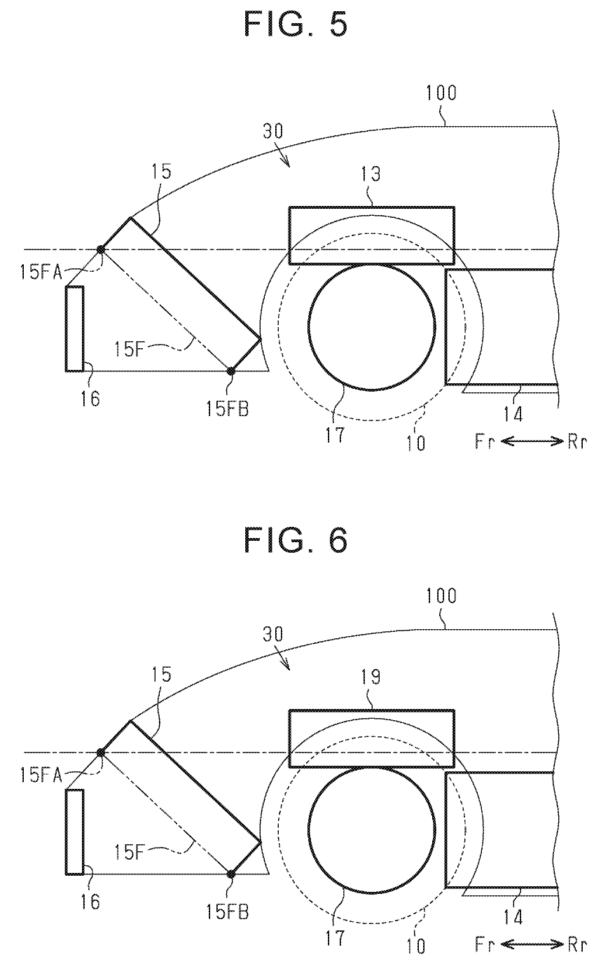

FIG. 5 illustrates layout of equipment in the compartment 30 when the battery electric vehicle 100 according to a second modification is viewed from the left side of an occupant facing forward in the battery electric vehicle 100.

As illustrated in FIG. 5, the battery electric vehicle 100 according to the second modification includes the on-board charger 13 as the electric equipment installed above the drive device 17.

The long dashed short dashed line in FIG. 5 indicates the height of the upper end 15FA of the front face portion 15F. As illustrated in FIG. 5, the upper end 15FA is situated at a position lower than an upper end of the on-board charger 13.

In this case, the electrical equipment is the on-board charger 13 that converts external alternating current electricity into direct current electricity and performs supply thereof to the battery 14.

FIG. 6 illustrates layout of equipment in the compartment 30 when the battery electric vehicle 100 according to a third modification is viewed from the left side of an occupant facing forward in the battery electric vehicle 100.

As illustrated in FIG. 6, the battery electric vehicle 100 according to the third modification includes an inverter 19 as electric equipment installed above the drive device 17. The inverter 19 converts the direct current electricity stored in the battery 14 into alternating current electricity and performs supplying thereof to the drive device 17. Specifically, the inverter 19 converts the direct current electricity stored in the battery 14 into alternating current electricity and performs supplying thereof to the motors 20.

The long dashed short dashed line in FIG. 6 indicates the height of the upper end 15FA of the front face portion 15F. As illustrated in FIG. 6, the upper end 15FA is situated at a position lower than an upper end of the inverter 19.

In this case, the electric equipment is the inverter 19 that converts direct current electricity stored in the battery 14 into alternating current electricity and performs supply thereof to the drive device 17.

What is claimed is:

1. A battery electric vehicle that drives front wheels by electricity supplied from a battery, the battery electric vehicle comprising:
a drive device including a motor and a reducer that transmits rotations by the motor to a drive shaft;
electrical equipment;
a condenser that cools refrigerant gas by outside air; and
a front grille for supplying outside air to the condenser, wherein
the drive device is of a uniaxial structure in which the reducer and the drive shaft are disposed on an extension of a rotation axis of the motor, and is disposed between the front wheels on right and left sides,
the electric equipment is disposed above the drive device,
the condenser is disposed forward of the drive device,
the front grille is disposed forward of the condenser,
the condenser is inclined such that an upper end of a front face portion that receives outside air from the front grille is situated forward of a lower end of the front face portion, and
the upper end of the front face portion is situated at a position lower than an upper end of the electric equipment.

2. The battery electric vehicle according to claim 1, wherein the electrical equipment is a power conversion device in which are integrated a DC-to-DC converter that boosts voltage of external electricity and performs supply of the voltage that is boosted to a battery, and an on-board charger that converts external alternating current electricity into direct current electricity, and supplies the direct current electricity to the battery.

3. The battery electric vehicle according to claim 1, wherein the electric equipment is a DC-to-DC converter that boosts voltage of external electricity, and supplies the voltage that is boosted to the battery.

4. The battery electric vehicle according to claim 1, wherein the electrical equipment is an on-board charger that converts external alternating current electricity into direct current electricity, and supplies the direct current electricity to the battery.

5. The battery electric vehicle according to claim 1, wherein the electric equipment is an inverter that converts direct current electricity stored in the battery into alternating current electricity, and supplies the alternating current electricity to the drive device.
